(19) United States
(12) Patent Application Publication
(10) Pub. No.: US 2026/0371515 A1
(43) Pub. Date: Nov. 19, 2026

(54) MODULAR PATCH PANEL BRACKETS TO ORGANIZE CABLES EXTENDING INTO A SERVER RACK

(71) Applicant: INTERNATIONAL BUSINESS MACHINES CORPORATION, ARMONK, NY (US)

(72) Inventors: Cody John Erie, Taopi, MN (US); Shawn Deutchman, Poughkeepsie, NY (US); Christopher Ciraulo, Wappinger Falls, NY (US); Blake Overton, Olivebridge, NY (US); John Torok, Poughkeepsie, NY (US); Camillo Sassano, Durham, NC (US); Flavia Gnecco, Newton, MA (US)

(21) Appl. No.: 19/210,669

(22) Filed: May 16, 2025

(51) Int. Cl. H05K 7/14

(52) U.S. Cl. CPC H05K 7/1491

(57) ABSTRACT

Provided are a modular patch panel bracket, an enclosure for modular patch panel brackets, and a server rack having an enclosure of modular patch panel brackets to organize cables extending into the server rack. A patch panel bracket comprises a patch panel portion having a plurality of ports on both sides of the patch panel portion to couple cables connecting to ports on the both sides and a mounting portion coupled to the patch panel portion. A mounting plate is attached to a surface with respect to the server rack and is adapted to engage the mounting portion of the patch panel bracket.

### STATEMENT REGARDING PRIOR DISCLOSURES BY THE INVENTOR OR A JOINT INVENTOR

IBM Z: 9175 Installation Manual for Physical Planning Model ME1, Document No. GC28-7049-00, published by International Business Machines Corp., pp. 218 (Apr. 2025).

### BACKGROUND OF THE INVENTION

Provided are a modular patch panel bracket, an enclosure for modular patch panel brackets, and a server rack having an enclosure of modular patch panel brackets to organize cables extending into the server rack.

A server rack comprises an enclosure of assemblies housing network computing components. Server racks are deployed in data centers. Numerous cables may extend from the data center into the server rack. A server rack may include an enclosure that incorporates a patch panel. The patch panel serves as a centralized location for organizing and connecting I/O and network cables between servers, switches, routers, and the cabling infrastructure. The patch panel organizes connections.

The patch panel is rack mounted and extends across the width of the rack having multiple ports for Ethernet, fiber optic, coaxial, etc. The patch panel has a front side with labeled ports where patch cables connect to network devices in the rack, such as switches or servers. The patch panel has a back side with termination points where cables from the data center are connected.

### SUMMARY

Provided are a modular patch panel bracket, an enclosure for modular patch panel brackets, and a server rack having an enclosure of modular patch panel brackets to organize cables extending into the server rack. A patch panel bracket comprises a patch panel portion having a plurality of ports on both sides of the patch panel portion to couple cables connecting to ports on the both sides and a mounting portion coupled to the patch panel portion. A mounting plate is attached to a surface with respect to the server rack and is adapted to engage the mounting portion of the patch panel bracket.

### BRIEF DESCRIPTION OF THE DRAWINGS

FIGS. 1A, 1B, and 1C, illustrate embodiments of an enclosure having patch panel brackets with patch panel portions to organize cables.

FIGS. 2A, 2B, and 2C, illustrate embodiments of a patch panel bracket and mounting plate to mount patch panel brackets.

FIGS. 3A, 3B, 3C, and 3D, illustrate embodiments of how a patch panel bracket is mounted into a mounting plate and disengaged from the mounting plate.

FIG. 4 illustrates an embodiment of patch panel brackets and cable loop attachments to mount into a line of mounting plates.

FIG. 5 illustrates an embodiment of an enclosure for a server rack having multiple patch panel brackets and spools to spool cables from the patch panel brackets.

FIG. 6 illustrates an embodiment of an enclosure for a server rack having patch panel brackets and cable loop attachments to organize cables extending into the server rack.

FIG. 7 illustrates an embodiment of power cables extending into the enclosure of the server rack.

### DETAILED DESCRIPTION

The ever-increasing demand for information technology (IT) rack density has placed a premium on space to manage overall system operational costs and sustainability. To address this, the IT data center industry has moved towards more efficient installations residing on slab (no-raised floor) and use of overhead cabling to connect IT equipment to the storage and networking infrastructure. Further, as rack densities have increased, the amount of cabling to be hosted and managed has increased, placing an ever-increasing demand on the rack's design, including the means to manage cabling egress, exit and overall slack management.

Described embodiments provide improvements to organizing cables extending into a server rack by providing an enclosure to affix to the server rack having modular patch panel brackets that can be added to or removed from the enclosure to accommodate the connection requirements for the server rack. Described embodiments further provide techniques to cover and lock the enclosure having the modular patch panel brackets to provide security for the cable connections.

In further embodiments, the enclosure of the modular patch panel brackets may be located at the top of the server rack to accommodate the changing data center environment where data centers tend to route a large number of optical fiber cables to the top of the server rack.

Further, providing modular patch panel brackets with patch panels allows the server rack manager to connect and disconnect cables at the patch panel brackets, and then mount the patch panel brackets in the enclosure after connecting external cables and internal cables coming from components within the server rack. The patch panel brackets are provided in a modular fashion to optimize costs. In operation, the modular patch panel brackets can be mounted to a temporary workstation mount contained separately within the enclosure to enhance user accessibility

Described embodiments provide modular spools to spool cables extending from the patch panel bracket into the interior of the server rack to manage excessive cable length, provide strain relief to the cables and prevent undue bending of the network and fiber optic cables.

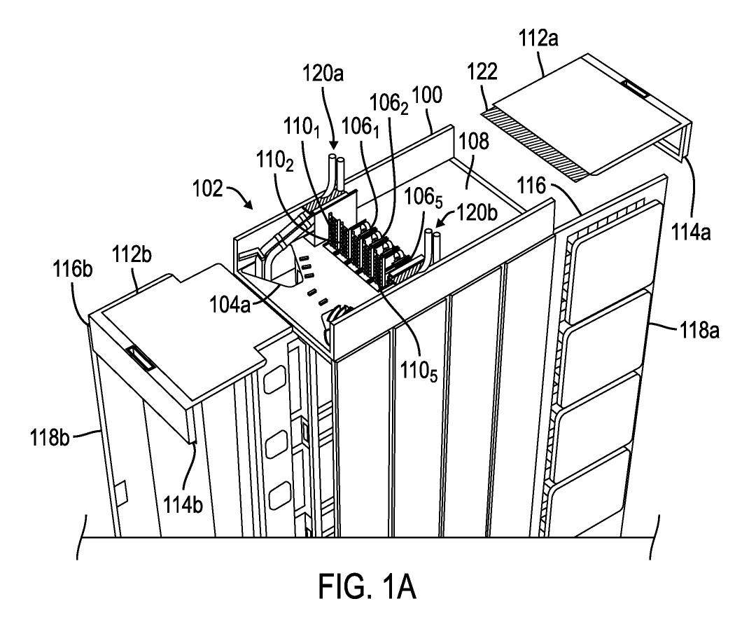

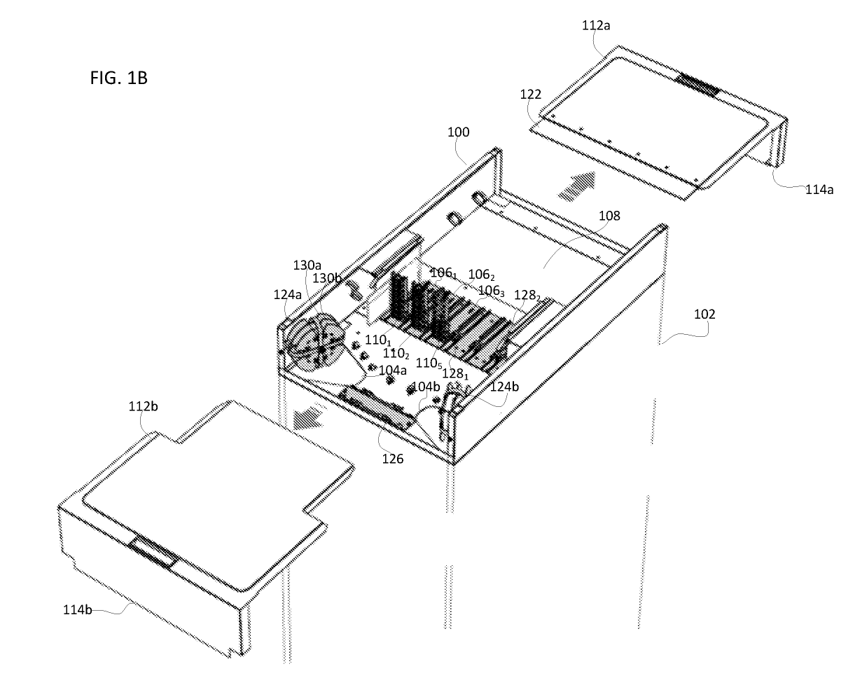

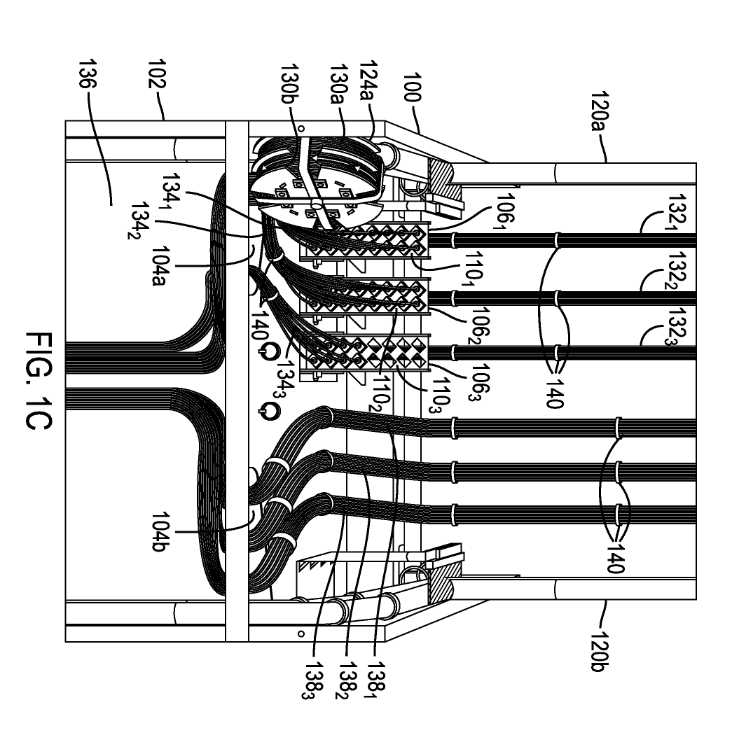

FIG. 1A illustrates an embodiment of an enclosure 100 attached to a server rack 102. The enclosure 100 includes an opening 104ainto an interior region or interior of the server rack 102. A plurality of patch panel brackets 106₁, 106₂…106₅are attached to a surface 108 of the enclosure 100. The patch panel brackets have vertical oriented patch panel portions 110₁, 110₂…110₅to connect to cables extending from outside of the server rack 102 into an interior of the server rack 102. Removable covers 112a, 112b may be slidably coupled to a top surface or area of the enclosure 100 to provide an enclosure of the enclosure 100. The slidable cover 112a has a lower flange 114a to engage an inner surface of the upper edge 116 of a front server rack door 118a to remain locked-in while the door 118a is locked. Similarly, slidable cover 112b also has a lower flange 114b to engage an inner surface of an upper edge 116b of the back server rack door 118b to remain locked-in while the back door 118b is locked.

In certain embodiments, the enclosure’s 100 external size may span the entire top surface of the rack profile thereby acting as the system's fire enclosure, providing a means to externally seal the system in airflow containment, installation (either hot or cold aisle). Further, the enclosure may be locked in place when the external door of the server rack is locked to prevent (secure) inadvertent or nefarious access to the cabling structure. Yet further, the enclosure may have sliding access lids (one from the system front and one from the system's rear) and a series of brushed fiber and/or foam elements 122 to seal and to strain relieve cables entering/exiting the enclosure.

Power cables 120a, 120b may extend through the brushed fibers in the opening 122 into the enclosure 100 and through the openings 104a.

FIG. 1B shows a further view of the enclosure 100 having a cable spool 124a to spool cables coming extending from the patch panel portions 110₁, 110₂, 110₃ to the opening 104a. Spool 124b may spool cables coming directly through the opening 122 of the top cover 112a that do not connect through patch panel portions. FIG. 1B further shows an additional workbench mounting plate 126 to engage an additional patch panel bracket, such as patch panel bracket 106₁. The server rack manager may attach the external and internal cables to a patch panel bracket mounted in the workbench mounting plate 126, and then move the completed patch panel bracket from the workbench mounting plate 126 to an available mounting plate 128₁, 128₂.

The cable spool 124a is shown as having two channels 130a, 130b to receive cables from different patch panel portions, such as 110₁, 110₂. This allows specific groups of cables to be wound in the cable spool 124a, 124b in separate channels to further organize the cables, such as cables connected to different patch panel brackets. The spools manage excess optical fiber cable length while maintaining the required bend radii for the cables.

FIG. 1C shows a further view of the enclosure 100 having three patch panel brackets 106₁, 106₂, 106₃with patch panel portions 110₁, 110₂, 110₃ having ports on one side (not visible) connected to external cables 132₁, 132₂, 132_{3.} Cables 134₁, 134₂, 134₃ coming from the interior 136 of the server rack extend through the opening 104a to connect to the patch panel portions 110₁, 110₂, 110₃. Pass-through cables 138₁, 138₂, 138₃do not connect to any patch panel brackets and instead extend directly from outside the server rack 102 through opening 104b to the interior 136 of the server rack 102. Loop fasteners 140 are dispersed through the enclosure 100 to fasten cables.

In FIG. 1C, only one side of the enclosure 100 includes the spooler 124a. The spoolers are modular and may be attached and removed from either side of the enclosure. As shown, the spooler 124a has two channels 130a, 130b with cables connected to patch panel portions 110₁, 110₂, respectively. Cables from patch panel portion 110₃ extend directly into the opening 104a without going through the spooler 124a. The spooler 124a ensures that cables are maintained at a minimum bend radius so that the cables extend into the interior of the server rack without harmful bending. Excessive bending of fiber optic cables can damage the fibers and harm performance. The arrows shown in channel 130b illustrate the directional flow of the cables.

Power cables 120a, 120b are also shown guided through the enclosure 100 in FIG. 1C through the openings 104a, 104b in an arrangement that maintains the power cables physically separate from the network or fiber optic cables 132₁, 132₂, 132₃, 138₁, 138₂, 138₃. This prevents charge passing through the power cables 120a, 120b from affecting the transmission of signals through the network/fiber optic cables.

With the embodiment of FIG. 1C, with the access covers removed, cable egress is optimized through the compartmentalization of the area contained within the enclosure. Specifically, bulk power cables 120a, 120b are routed and strain-relieved to the side(s) of the enclosure through dedicated channels. Similarly, Ethernet communications cables are routed. In the case of optical fiber cabling, the arrangement of FIG. 1C supports two applications, point-to-point cabling and structured cabling.

With point-to-point cabling, such as cables 138₁, 138₂, 138₃, bulk optical fiber cabling is provided a large horizontal surface for strain relief. In doing so, a significant amount of surface area is provided to ensure the required bend radius is attained. In addition, strain relief features are provided to ensure cables are not inadvertently damaged during internal system or external cabling servicing, respectively.

With structured cabling, such as cables 132₁, 132₂, 132₃, patch panel brackets are used to transition from a single bulk cable to individual fiber pairs connecting to their end-points. This cabling design is optimized for "localized" patch paneling deployments.

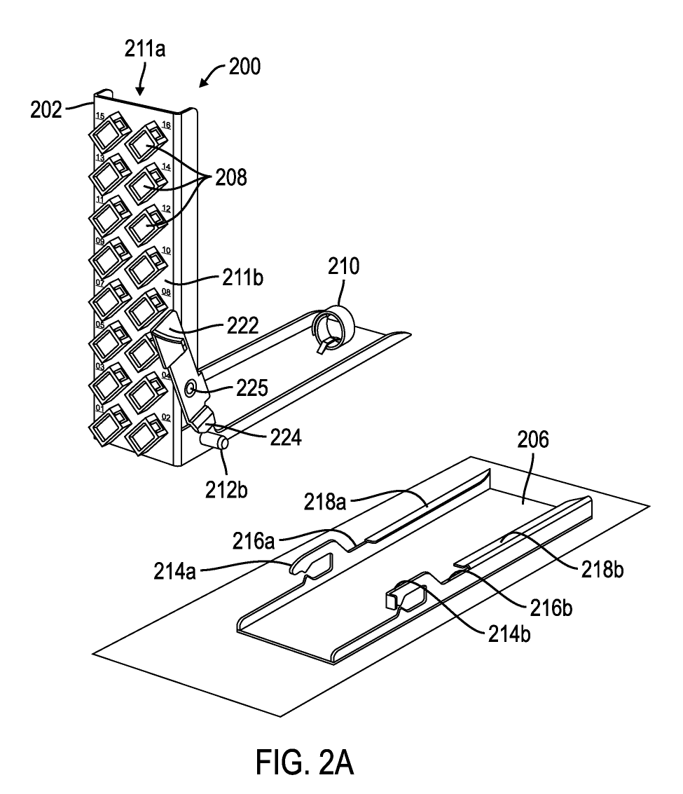

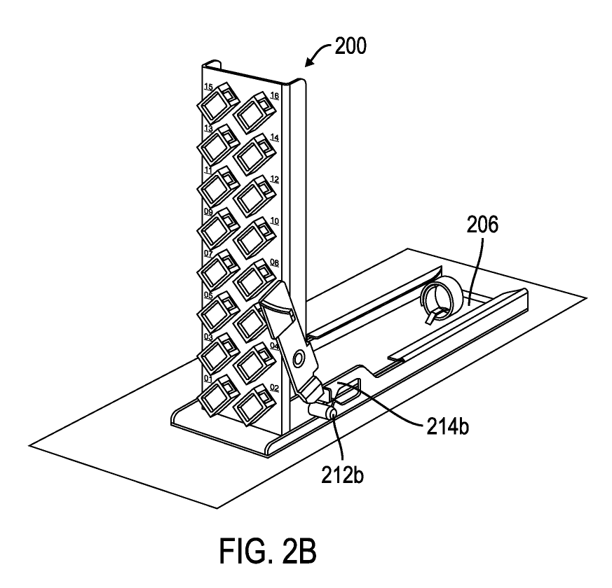

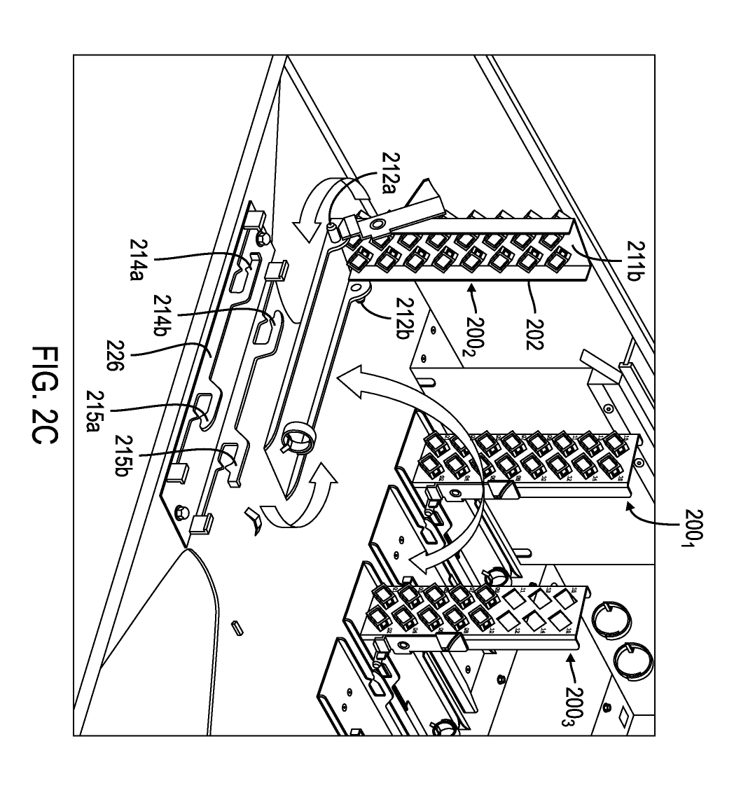

FIG. 2A illustrates an embodiment of a patch panel bracket 200, such as brackets 106₁, 106₂, 106₃in FIGS. 1A, 1B, 1C, having a patch panel portion 202 and a mounting portion 204 that engages a mounting plate 206 on a surface of the enclosure. The patch panel portion 202 and mounting portion 204 are approximately perpendicular to each other. When the patch panel bracket is mounted, the patch panel portion extends outward perpendicular to a surface of the server rack.

The patch panel portion 202 includes a plurality of couplers 208 to which cables on each side of the patch panel portion 202 connect. The couplers 208 provide an electrical connection between cables extending from outside of the server rack to cables extending into the interior of the server rack. The mounting portion 204 includes a loop fastener 210 to fasten the cables coming from outside of the server rack connecting to a side 211a (shown in FIG. 2C) of the patch panel portion 202 opposite the shown side 211b.

The mounting portion 204 may include pins 212a, 212b on each side (pin 212a is shown in FIG. 2C). The pins 212a, 212b engage with slots 214a, 214b on the mounting plate 206, where the slots 214a, 214b mechanically fasten the pins 212a, 212b. The mounting plate 206 includes side rails 216a, 216b having flange portions 218a, 218b extending inward toward a center of the mounting plate 206. The mounting portion 204 of the patch panel bracket 200 includes side rails 220a, 220b that are adapted to slidably mount inside the side rails 216a, 216b of the mounting plate. The outer side of the side rails 220a, 220b of the mounting portion 204 are flush against the inner side of the side rails 220a, 220b of the mounting plate 206. The flange portions 218a, 218b maintain the side rails 216a, 216b in position within the mounting plate.

The patch panel portion 202 includes on one side a lever 222 that may be mechanically rotated downward to force an edge portion 224 to apply lateral force to the edge of the slot 214b to mechanically disengage the patch panel bracket 200 from the mounting plate by pushing the pin 212 away from the slot 214b. The lever 222 is rotatably mounted to a side of the patch panel portion to rotate around a shaft 225 extending from a side of the patch panel portion 202. The lever 222 mechanism is devised to optimize ease of installation and removal of the modular patch panel bracket.

FIG. 2B shows the patch panel bracket 200 mounted within the mounting plate 206, with the pin 212b engaged with the slot 214b. Another pin 212a (shown in FIG. 2C), would engage with slot 214a.

FIG. 2C shows how a patch panel bracket 200₂may be removed from mounting plate 206₂and moved to a workbench mounting plate 226 to allow a server rack manager to more easily access the patch panel portion 202 ports to connect cables. The arrows illustrate how the patch panel bracket 200₂may be maneuvered to be disengaged from mounting plate 206₂and placed within workbench mounting plate 226. In this way, the server rack manager may move any of the patch panel brackets 200₁, 200₂, 200₃to the workbench mounting plate 226 for ease of access to the ports on the sides of the patch panel portion 202₂. The workbench mounting plate 226 includes two sets of slots 214a, 214b and 215a, 215d to allow the patch panel bracket pins 224a, 224b to engage either set of slots 214a, 21b and 215a, 215b to be placed in either direction for convenience of the server rack manager.

Once mounted to the temporary workbench mounting plate 226, the server rack manager does not need to manually hold onto the modular patch panel while installing or removing the cabling. Further, once the cabling is installed, the cable is locally strain relieved to the workbench mounting plate prior to removing the modular patch panel bracket from the workbench mounting plate and installing the adjusted patch panel bracket to its position within the enclosure's base. In doing so, the optical fibers are inherently protected via ensuring required cable bend radii are not violated.

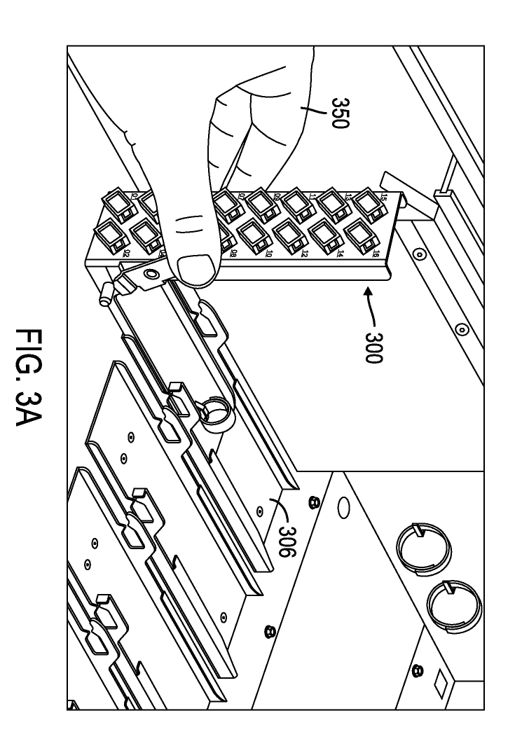

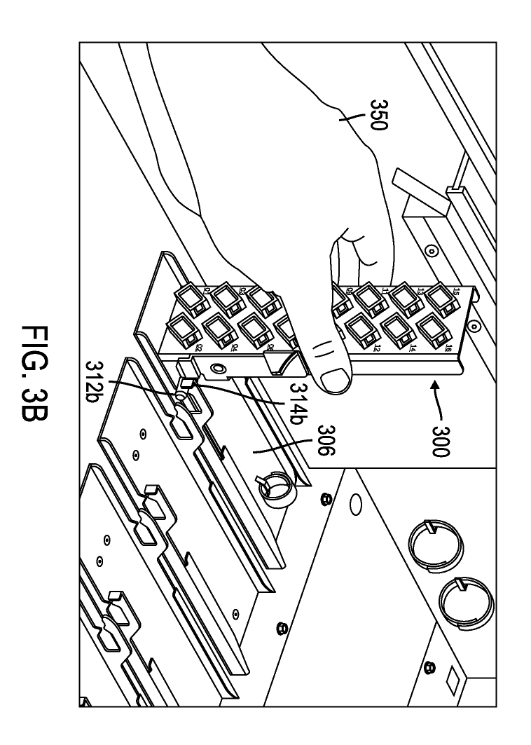

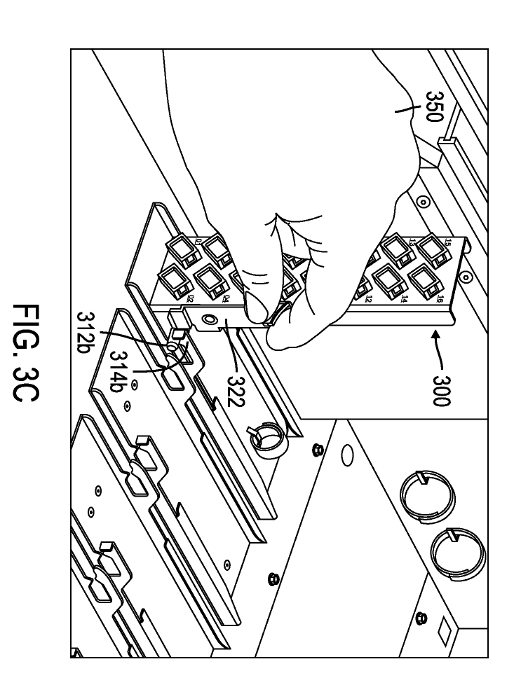

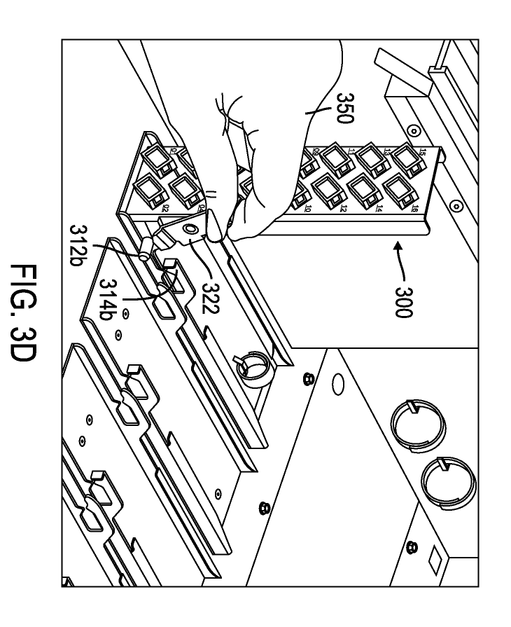

FIG. 3A illustrates an embodiment of a server rack manager 350 slidably inserting a patch panel bracket 300, such as patch panel bracket 200 in FIG. 2A, 2B, 2C, into a mounting plate 306, such as mounting plate 206.

FIG. 3B illustrates an embodiment of the server rack manager 350 slidably pushing a pin 312b, such as pin 212b, of the patch panel bracket 300 to engage slot 314b, such as slot 214b, of the mounting plate 306. The pin 312b is pushed to mechanically lock into the slot 314b.

FIG. 3C illustrates an embodiment of the server rack manager 350 rotating the lever 322, such as lever 222 in FIGS. 2A, 2B, 2C, downward to bias the lever 322 against the slot 314b to disengage the pin 312b from the slot 314b.

FIG. 3D shows the result of the lever 322 rotated downward with the pin 312b disengaged from the slot 314b.

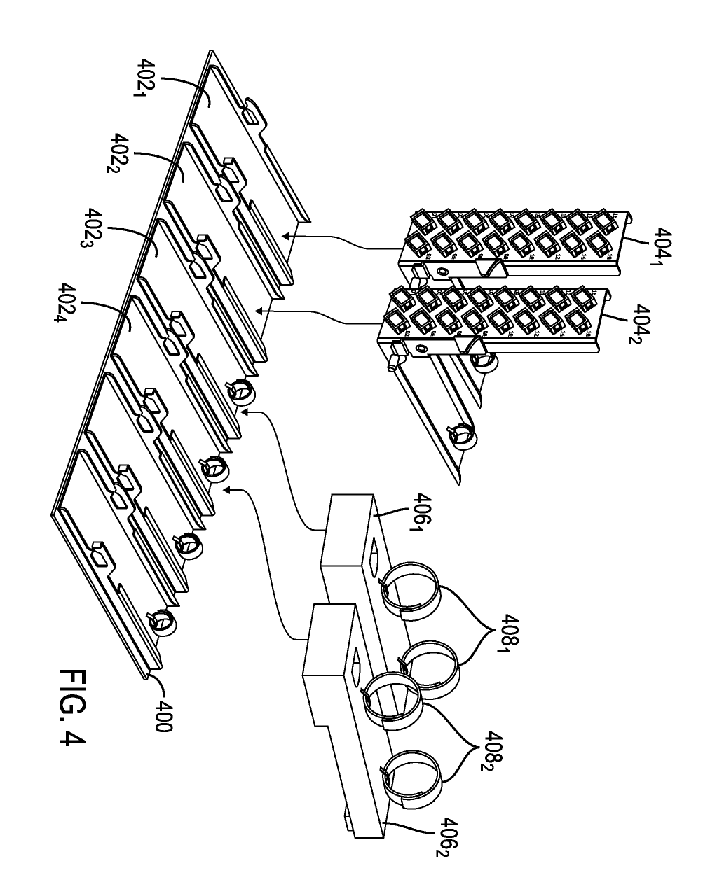

FIG. 4 illustrates a panel 400 having mounting plates 402₁, 402₂, 402₃, 402₄arranged in a line. Mounting plates 402₁and 402₂may engage patch panel brackets 404₁and 404₂, respectively. Cable loop attachments 406₁and 406₂include loop fasteners 408₁and 408₂, respectively, to fasten bypass cables extending from outside of the server rack into the interior region of the server rack without connecting to patch panel brackets. The cable loop attachments 406₁ and 406₂may mate with mounting plates 402₃and 402₄, respectively.

With the embodiment of FIG. 4, different types of mounts may be engaged with any of the mounting plates, including patch panel brackets, cable loop attachments, and other types of mounts for different types of engagements with cables.

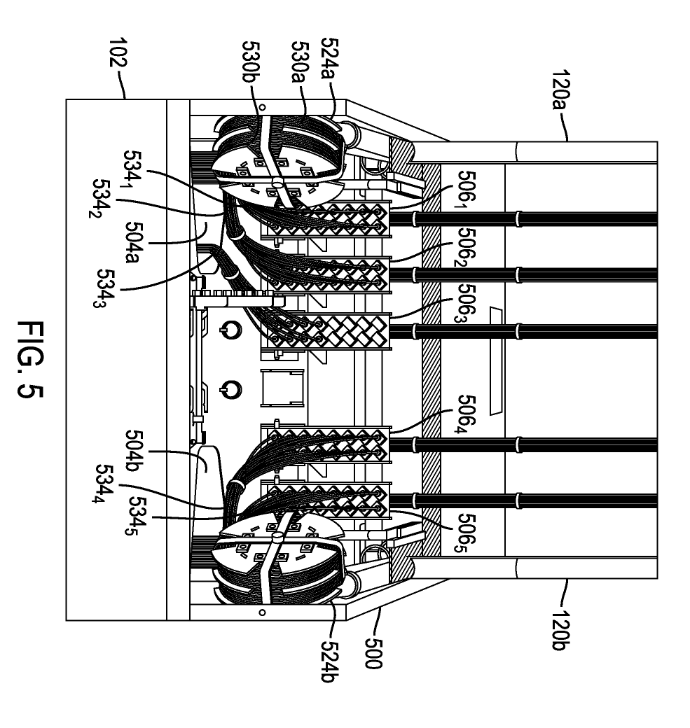

FIG. 5 illustrates an arrangement of the enclosure 500 having two spools 524a, 524b on opposite sides of the enclosure 500. Spool 524a spools cables 534₁, 534₂from patch panel brackets 506₁, 506₂in spool channels 530a, 530b. Cables 534₃from patch panel bracket 506₃extend directly into opening 504a without being spooled. Spool 524b spools cables 534₄, 534₅from patch panel brackets 506₄, 506₅that extend into opening 504b.

With the embodiment of FIG. 5, spools may be added and removed depending on the cable arrangement. Additional patch panel brackets may be inserted into the mounting plates to handle different arrangements of cables combing into the server rack. The enclosure allows for adding modular components into the mounting plates and modular spools to accommodate different cabling needs. For instance, spooling may not be needed for cables 534a because they extend to the components in the server rack without having much slack to require spooling to avoid bending of the cables.

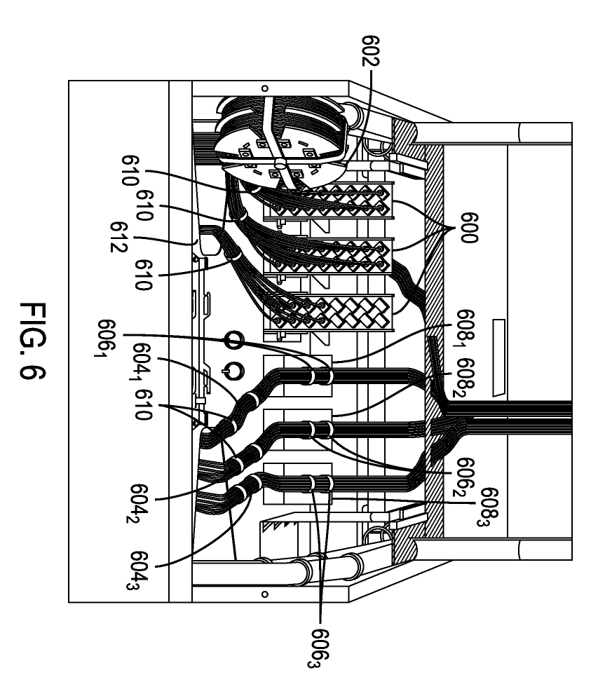

FIG. 6 illustrates a further embodiment where there are three patch panel brackets 600 from which cables extend that are wound on spool 602. Bypass cables 604₁, 604₂, 604₃ are fastened by the loop fasteners 606₁, 606₂, 606₃of cable loop attachments 608₁, 608₂, 608₃, such as cable loop attachments 406₁, 406₂and loop fasteners 408₁, 408₂ in FIG. 4. Additional loop fasteners 610 on the enclosure surface 612 may also provide further fastening of the cables. In this way, the server rack manager may change the modular attachments from patch panel brackets to cable loop attachments depending on the cabling types in the system, whether bypass cables not requiring patch panels are used versus cabling that is suitable for patch panels.

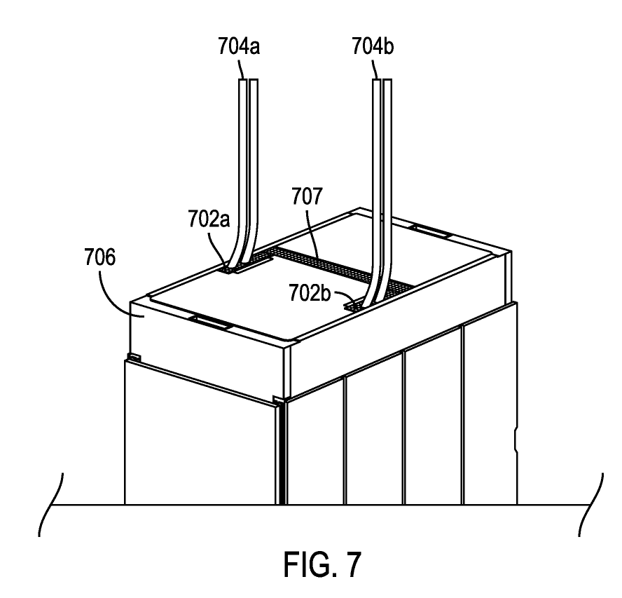

FIG. 7 provides a further embodiment where the enclosure cover 700 includes side openings 702a, 702b to allow power cables 704a, 704b to enter the enclosure 706 separate from the opening 706 where the network/fiber optic cables ingress. Providing physically separate openings 702a, 702b and 706 avoid the power cables from electronically interfering with transmissions in the network cables. The openings 702a, 702b, 706 are covered by filter brushes that filter out dust particles from entering the enclosure 700.

Described embodiments furth include methods to attach modular patch panel brackets and modular cable loop attachments to the mounting plates, connect cables to the ports in the patch panel brackets engaged with the mounting plates, attach spools to the enclosure to spool cales extending through an opening in the enclosure into the server rack interior. Described embodiments further include methods to mount and remove the patch panel brackets and cable loop attachments to mounting plates in any arrange on a surface of the enclosure.

In the described embodiment, variables i, n, etc., when used with different elements may denote a same or different instance of that element.

The terms "an embodiment", "embodiment", "embodiments", "the embodiment", "the embodiments", "one or more embodiments", "some embodiments", and "one embodiment" mean "one or more (but not all) embodiments of the present invention(s)" unless expressly specified otherwise.

The terms "including", "comprising", “having” and variations thereof mean "including but not limited to", unless expressly specified otherwise.

The enumerated listing of items does not imply that any or all of the items are mutually exclusive, unless expressly specified otherwise.

The terms "a", "an" and "the" mean "one or more", unless expressly specified otherwise.

Terms such as “top”, bottom”, “upper”, “lower”, "rear", "front", "back", "outer", "inner", "bottom", "left", and the like may be used for descriptive purposes only and are not to be construed as limiting. Embodiments may be manufactured, used, and contained in a variety of positions and orientations.

Devices that are in communication with each other need not be in continuous communication with each other, unless expressly specified otherwise. In addition, devices that are in communication with each other may communicate directly or indirectly through one or more intermediaries.

A description of an embodiment with several components in communication with each other does not imply that all such components are required. On the contrary a variety of optional components are described to illustrate the wide variety of possible embodiments of the present invention.

When a single device or article is described herein, it will be readily apparent that more than one device/article (whether or not they cooperate) may be used in place of a single device/article. Similarly, where more than one device or article is described herein (whether or not they cooperate), it will be readily apparent that a single device/article may be used in place of the more than one device or article or a different number of devices/articles may be used instead of the shown number of devices or programs. The functionality and/or the features of a device may be alternatively embodied by one or more other devices which are not explicitly described as having such functionality/features. Thus, other embodiments of the present invention need not include the device itself.

The foregoing description of various embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto. The above specification, examples and data provide a complete description of the manufacture and use of the composition of the invention. Since many embodiments of the invention can be made without departing from the spirit and scope of the invention, the invention resides in the claims herein after appended.

What is claimed is:

1. A patch panel system for a server rack, comprising:
a patch panel bracket comprising:
a patch panel portion having a plurality of ports on both sides of the patch panel portion to couple cables connecting to ports on the both sides;
a mounting portion coupled to the patch panel portion; and
a mounting plate adapted to attach to a surface with respect to the server rack and to engage the mounting portion of the patch panel bracket.

2. The patch panel system of claim 1,
wherein the mounting portion includes a first pin on a first side of the mounting portion and a second pin on a second side of the mounting portion, and
wherein the mounting plate includes a first slot on a first side of the mounting plate and a second slot on a second side of the mounting plate a slot, wherein the first slot includes a first opening to engage the first pin and the second slot includes a second opening to engage the second pin.

3. The patch panel system of claim 2, wherein the mounting portion includes a lever that when moved downward has a first end that applies a force to a surface of the first slot to disengage the first pin from the first slot and the second pin from the second slot to disengage the patch panel bracket from the mounting plate.

4. The patch panel system of claim 1,
wherein the mounting plate includes a first rail on a first side of the mounting plate, wherein the first rail has a first flange extending inward toward a center of the mounting plate and a second rail on a second side of the mounting plate, wherein the second rail has a second flange extending inward toward the center of the mounting plate, and
wherein the mounting portion of the patch panel bracket has a first rail on a first side of the mounting portion and a second rail on a second side of the mounting portion, wherein the first rail and the second rail are adapted to slide along an inner surface of the first rail and the second rail of the mounting plate under the first flange and the second flange, respectively.

5. The patch panel system of claim 1, wherein the mounting portion and the patch panel portion are approximately perpendicular, wherein the patch panel portion extends outward perpendicular to the surface the server rack when the mounting portion is engaged with the mounting plate.

6. A cable management system for a server rack, comprising:
an enclosure having a surface;
a plurality of mounting plates coupled to the surface;
a plurality of patch panel brackets, each patch panel bracket comprising:
a patch panel portion having a plurality of ports on both sides of the patch panel portion to couple cables connecting to ports on the both sides; and
a mounting portion coupled to the patch panel portion, wherein the mounting portion is adapted to engage one of the mounting plates to be removably coupled to the one of the mounting plates; and
an opening in the surface of the enclosure through which cables that connect to ports on one side of the patch panel portion extend into an inner region of the server rack to connect to components in the server rack.

7. The cable management system of claim 6, further comprising:
a plurality of cable loop attachments, wherein each cable loop attachment includes a cable loop to fasten cables extending from outside the server rack and into an interior region of the server rack, wherein each of the cable loop attachments is adapted to engage one of the mounting plates to be removably coupled to the mounting plates.

8. The cable management system of claim 6, wherein the enclosure is adapted to be positioned on a top surface of the server rack, wherein the opening in the surface of the enclosure is flush with an opening of the top surface of the server rack, wherein the opening in the enclosure is adapted to allow cables to extend through the opening in the surface of the enclosure through the opening of the top surface into the inner region of the server rack.

9. The cable management system of claim 8, further comprising:
a spool mounted on a side of the enclosure, wherein the spool is adapted to spool cables connected to the ports on one side of the patch panel portion that extend through the opening into the inner region of the server rack.

10. The cable management system of claim 9, wherein the spool further includes:
a first channel;
a second channel; and
at least one separator between the first channel and the second channel, wherein the first channel and the second channel are adapted to spool cables connected to different patch panel brackets.

11. The cable management system of claim 6, further comprising:
a cover removably coupled to the enclosure to cover an opening in the enclosure.

12. The cable management system of claim 11, wherein the cover extends along a top opening of the enclosure and a side opening of the enclosure to enclose the enclosure, wherein a side of the cover extending across the side opening includes a flange extending downward from the side of the cover extending across the side opening, wherein the flange is adapted to engage an inner surface of a server rack door to maintain the cover locked in place when the server rack door is locked.

13. The cable management system of claim 11, wherein the cover includes:
a first opening on a first side of the cover; and
a second opening on a second side of the cover, wherein the first and the second openings are adapted to receive power cables extend into the inner region of the server rack.

14. The cable management system of claim 6, wherein the enclosure is affixed to the server rack.

15. The cable management system of claim 6, wherein the mounting portion and the patch panel portion are approximately perpendicular, wherein the patch panel portion extends perpendicular and outward from the surface toward a top of the enclosure when the patch panel portion is engaged with a mounting plate.

16. The cable management system of claim 6, further comprising:
a cover removably coupled to the enclosure to cover an opening in the enclosure; and
a cover opening along a top surface of the cover adapted to receive cables from outside of the server rack, wherein the patch panel brackets are engaged with mounting plates extending in a line across the surface of the enclosure, wherein patch panel portions of the patch panel brackets extend perpendicular from the mounting plates, and wherein the patch panel portions are adapted to receive cables extending through the cover opening.

17. The cable management system of claim 6, wherein the patch panel brackets are engaged with the mounting plates extending in a line across the surface of the enclosure, further comprising:
an additional mounting plate positioned on the surface away from the line of the mounting plates, wherein the additional mounting plate is adapted to engage one of the patch panel brackets.

18. A server rack, comprising:
an enclosure including racks for computer components;
an enclosure affixed to the enclosure, comprising:
a surface;
a plurality of mounting plates coupled to the surface;
a plurality of patch panel brackets, each patch panel bracket comprising:
a patch panel portion having a plurality of ports on both sides of the patch panel portion to couple cables connecting to ports on the both sides; and
a mounting portion coupled to the patch panel portion, wherein the mounting portion is adapted to engage one of the mounting plates to be removably coupled to the one of the mounting plates; and
an opening in the surface of the enclosure through which cables that connect to ports on one side of the patch panel portion extend into enclosure to connect to the computer components in the racks.

19. The server rack of claim 18, further comprising:
a plurality of cable loop attachments, wherein each cable loop attachment includes a cable loop to fasten cables extending from outside the server rack and into an interior region of the server rack, wherein each of the cable loop attachments is adapted to engage one of the mounting plates to be removably coupled to the mounting plates.

20. The server rack of claim 18, further comprising:
a cover removably coupled to the enclosure to enclose the enclosure; and
a cover opening along a top surface of the cover adapted to receive cables from outside of the server rack, wherein the patch panel brackets are engaged with mounting plates extending in a line across the surface of the enclosure, wherein patch panel portions of the patch panel brackets extend perpendicular from the mounting plates, and wherein the patch panel portions are adapted to receive cables extending through the cover opening.
